(19) United States
(12) Patent Application Publication
(10) Pub. No.: US 2021/0257446 A1
(43) Pub. Date: Aug. 19, 2021

(54) SEMICONDUCTOR DEVICE AND FABRICATION METHOD OF THE SEMICONDUCTOR DEVICE

(71) Applicant: KIOXIA CORPORATION, Tokyo (JP)

(72) Inventor: Toshitaka MIYATA, Yokkaichi Mie (JP)

(73) Assignee: KIOXIA CORPORATION, Tokyo (JP)

(21) Appl. No.: 17/012,345

(22) Filed: Sep. 4, 2020

(30) Foreign Application Priority Data
Feb. 19, 2020 (JP) 2020-026136

(51) Int. Cl. H01L 29/06; H01L 27/11556; H01L 27/11582; H01L 21/8234; H01L 21/762; H01L 29/49

(52) U.S. Cl. CPC H01L 29/0607; H01L 29/0653; H01L 27/11556; H01L 29/4933; H01L 21/8234; H01L 21/76224; H01L 27/11582

(57) ABSTRACT

According to a certain embodiment, the semiconductor device includes: a semiconductor region having a first conductivity type including a first surface; an insulating portion formed on the semiconductor region, and having a second surface moved backward in the depth direction of the semiconductor region more than the first surface; a first region disposed on the semiconductor region between a first portion and second portions of the insulating portion; a second region disposed on the semiconductor region between the first and second portions to be separated from the first region; a control electrode disposed above the first surface to be located between the first and second regions; a first electrode disposed on the first region so as to be contacted with the first region; and a first insulating film containing hafnium disposed on a side wall of the semiconductor region at a stepped portion between the first and second surfaces.

### CROSS REFERENCE TO RELATED APPLICATIONS

This application is based upon and claims the benefit of priority from prior Japanese Patent Application No. P2020-026136 filed on Feb. 19, 2020, the entire contents of which are incorporated herein by reference.

### FIELD

Embodiments described herein relate generally to a semiconductor device and a fabrication method of the semiconductor device.

### BACKGROUND

In recent years, in the LSI technology, a gate length has been shortened and junction depths of a source region and a drain region have been shallowed in order to realize integration and speed enhancement of device operation. Moreover, for example, a transistor size for driving a memory cell, such as NAND flash memory, is an important factor, in determining a Half Pitch (HP) of the memory cell.

### BRIEF DESCRIPTION OF THE DRAWINGS

FIG. 1A is a schematic planar pattern configuration diagram of a semiconductor device according to the embodiments.

FIG. 1B is a schematic planar pattern configuration diagram of the semiconductor device according to the embodiments in which an active region is reduced.

FIG. 1C is a schematic planar pattern configuration diagram of the semiconductor device according to the embodiments in which an edge portion of a source contact and an edge portion of a drain contact are reduced to be respectively contacted with insulating isolation regions.

FIG. 1D is a schematic planar pattern configuration diagram of the semiconductor device according to a modified example of the embodiments in which the edge portion of the source contact and the edge portion of the drain contact are reduced to respectively run on the insulating isolation regions.

FIG. 2A is a schematic cross-sectional structure diagram taken in the line I-I of FIG. 1C, in one process of a fabrication method of a semiconductor device according to a first embodiment (Phase 5).

FIG. 2B is a schematic cross-sectional structure diagram taken in the line I-I of FIG. 1C, in one process of the fabrication method of the semiconductor device according to the first embodiment (Phase 6).

FIG. 2C is a schematic cross-sectional structure diagram taken in the line I-I of FIG. 1C, in one process of the fabrication method of the semiconductor device according to the first embodiment (Phase 1).

FIG. 2D is a schematic cross-sectional structure diagram taken in the line I-I of FIG. 1C, in one process of the fabrication method of the semiconductor device according to the first embodiment (Phase 2).

FIG. 2E is a schematic cross-sectional structure diagram taken in the line I-I of FIG. 1C, in one process of the fabrication method of the semiconductor device according to the first embodiment (Phase 3).

FIG. 2F is a schematic cross-sectional structure diagram taken in the line I-I of FIG. 1C, in one process of the fabrication method of the semiconductor device according to the first embodiment (Phase 4).

FIG. 2G is a schematic cross-sectional structure diagram taken in the line II-II of FIG. 1D, in one process of a fabrication method of a semiconductor device according to a modified example of the first embodiment (Phase 1).

FIG. 2H is a schematic cross-sectional structure diagram taken in the line II-II of FIG. 1D, in one process of the fabrication method of the semiconductor device according to a modified example of the first embodiment (Phase 2).

FIG. 3A is a schematic cross-sectional structure diagram taken in the line I-I of FIG. 1C, in one process of a fabrication method of a semiconductor device according to a second embodiment (Phase 5).

FIG. 3B is a schematic cross-sectional structure diagram taken in the line I-I of FIG. 1C, in one process of the fabrication method of the semiconductor device according to the second embodiment (Phase 6).

FIG. 3C is a schematic cross-sectional structure diagram taken in the line I-I of FIG. 1C, in one process of the fabrication method of the semiconductor device according to the second embodiment (Phase 7).

FIG. 3D is a schematic cross-sectional structure diagram taken in the line I-I of FIG. 1C, in one process of the fabrication method of the semiconductor device according to the second embodiment (Phase 1).

FIG. 3E is a schematic cross-sectional structure diagram taken in the line I-I of FIG. 1C, in one process of the fabrication method of the semiconductor device according to the second embodiment (Phase 2).

FIG. 3F is a schematic cross-sectional structure diagram taken, in the line I-I of FIG. 1C, in one process of the fabrication method of the semiconductor device according to the second embodiment (Phase 3).

FIG. 3G is a schematic cross-sectional structure diagram taken in the line I-I of FIG. 1C, in one process of the fabrication method of the semiconductor device according to the second embodiment (Phase 4).

FIG. 3H is a schematic cross-sectional structure diagram taken in the line II-II of FIG. 1D, in one process of a fabrication method of a semiconductor device according to a modified example of the second embodiment (Phase 1).

FIG. 3I is a schematic cross-sectional structure diagram taken in the line II-II of FIG. 1D, in one process of a fabrication method of the semiconductor device according to the modified example of the second embodiment (Phase 2).

FIG. 3J is a schematic cross-sectional structure diagram taken in the line II-II of FIG. 1D, in one process of a fabrication method of the semiconductor device according to the modified example of the second embodiment (Phase 3).

### DETAILED DESCRIPTION

Next, certain embodiments will now be explained with reference to drawings. In the description of the following drawings to be explained, the identical or similar reference sign is attached to the identical or similar part. However, it should be noted that the drawings are schematic and the relation between thickness and the plane size and the ratio of the thickness of each component part differs from an actual thing. Therefore, detailed thickness and size should be determined in consideration of the following explanation. Of course, the part from which the relation and ratio of a mutual size differ also in mutually drawings is included.

Moreover, the embodiments described hereinafter merely exemplify the device and method for materializing the technical idea; and the embodiments do not specify the material, shape, structure, placement, etc. of each component part as the following. The embodiments may be changed without departing from the spirit or scope of claims.

It is effective to reduce an area of an active region and to reduce a distance between a source contact and an insulating isolation region, as one of methods of reducing a transistor size. However, as the distance between the source contact and the insulating isolation region is reduced, if the source contact runs on the insulating isolation region, since the distance between the source contact and the source diffusion junction becomes shorter, a junction leakage increases and thereby it difficult to reduce the transistor size.

Certain embodiments provide a semiconductor device capable of suppressing an increase in a junction leakage and reducing a size thereof, and a fabrication method of such a semiconductor device.

According to one embodiment, the semiconductor device includes a semiconductor region, an insulating portion, a first region (source), a second region (drain), a control electrode (gate electrode), a first electrode, and a first insulating film. The semiconductor region having a first conductivity type includes a first surface. The insulating portion is formed on the semiconductor region, and has a second surface formed so as to be moved backward in the depth direction of the semiconductor region more than the first surface. The first region is disposed on the semiconductor region between a first portion of the insulating portion and a second portion of the insulating portion. The second region is disposed on the semiconductor region between the first portion and the second portion, and is located to be separated from the first region. The control electrode is disposed above the first surface, and is located between the first region and the second region. The first electrode is disposed on the first region so as to be contacted with the first region. The first insulating film is disposed on a side wall of the semiconductor region at a stepped portion between the first surface and the second surface. The first insulating film is an insulating layer containing hafnium.

The semiconductor device according to the embodiments described hereinafter is intended for a Metal Oxide Semiconductor Field Effect Transistor (MOSFET). Moreover, in the embodiments described hereinafter, the insulating isolation region may simply be referred to as STI (Shallow Trench Isolation).

### First Embodiment

(Planar Pattern Configuration)

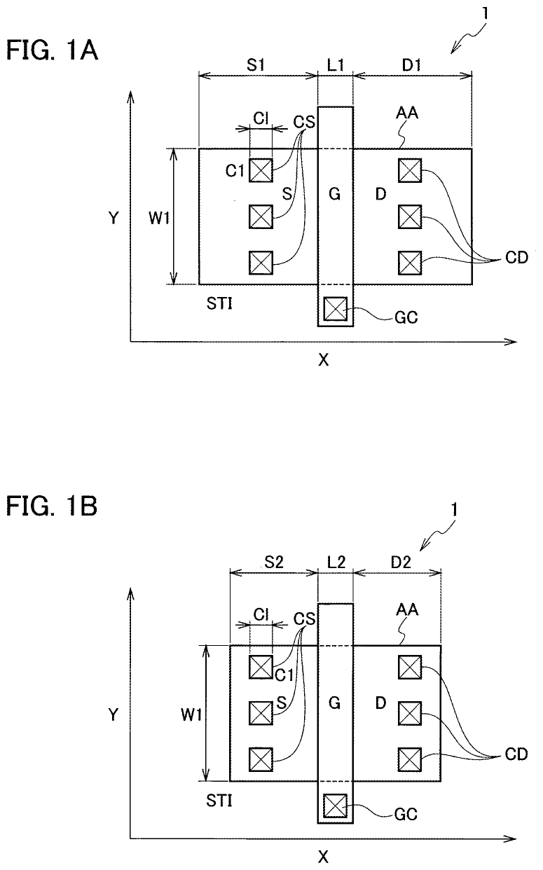

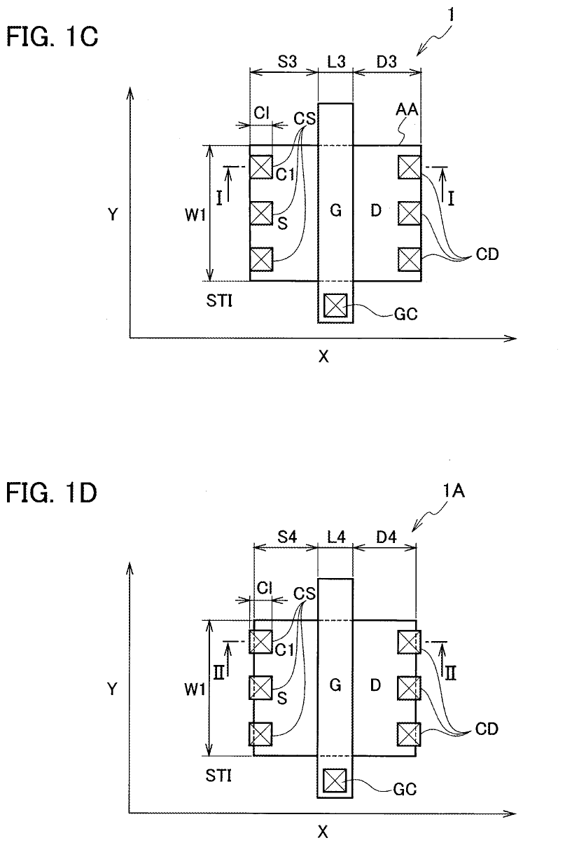

FIGS. 1A to 1C illustrate respectively schematic planar pattern configurations of a semiconductor device 1 according to a first embodiment to be disposed on an X-Y plane. FIG. 1D illustrates a schematic planar pattern configuration of a semiconductor device 1 according to a modified example of the first embodiment to be disposed on an X-Y plane.

As illustrated in FIG. 1A, the semiconductor device 1 according to the first embodiment includes a source region S and a drain region D, and a gate electrode G disposed to be sandwiched between the source region S and the drain region D. The active region AA includes the source region S and the drain region D, and a channel region disposed to be sandwiched between the source region S and the drain region D, and is surrounded by insulating isolation regions. The insulating isolation regions are formed of Shallow Trench Isolation (STI), for example. As illustrated in FIG. 1A, the size in the X direction of the source region S is expressed by S1, the size in the Y direction thereof is expressed by W1, the size in the X direction of the drain region D is expressed by D1, and the size in the Y direction thereof is expressed by W1. The size in the X direction of the gate electrode G is expressed by L1. W1 and L1 respectively correspond to the channel width and the channel length of the semiconductor device according to the embodiments. A source contact(s) CS is disposed on the source region S, and a drain contact(s) CD is disposed on the drain region D. A gate contact GC is disposed on a gate electrode G extended in the Y direction. The size of the source contact CS is expressed by C1 in the X direction, and is expressed by C1 in the Y direction. The size of the drain contact CD and the size of the gate contact GC are expressed similarly to that of the source contact CS.

FIG. 1B illustrates an example of a schematic planar pattern configuration of the semiconductor device 1 according to the first embodiment in which the active region AA is reduced in the X direction. As illustrated in FIG. 1B, the size in the X direction of the source region S is expressed by S2, the size in the Y direction thereof is expressed by W1, the size in the X direction of the drain region D is expressed by D2, and the size in the Y direction thereof is expressed by W1. In this case, S2<S1 is realized and D2<D1 is realized. The size in the X direction of the gate electrode G is expressed by L2. W1 and L2 respectively correspond to the channel width and the channel length. A source contact(s) CS is disposed on the source region S, and a drain contact(s) CD is disposed on the drain region D. A gate contact GC is disposed on a gate electrode G extended in the Y direction. The size of the source contact CS is expressed by C1 in the X direction, and is expressed by C1 in the Y direction. The size of the drain contact CD and the size of the gate contact GC are expressed similarly to that of the source contact CS.

FIG. 1C illustrates an example of a schematic planar pattern configuration of the semiconductor device 1 according to the first embodiment in which the active region AA is reduced in the X direction so that an edge portion of the source contact CS and an edge portion of the drain contact CD are respectively contacted with the insulating isolation regions STI. As illustrated in FIG. 1C, the size in the X direction of the source region S is expressed by S3, the size in the Y direction thereof is expressed by W1, the size in the X direction of the drain region D is expressed by D3, and the size in the Y direction thereof is expressed by W1. In this case, S3<S2<S1 is realized and D3<D2<D1 is realized. The size in the X direction of the gate electrode G is expressed by L3. W1 and L3 respectively correspond to the channel width and the channel length. A source contact(s) CS of which the edge portion is contacted with the insulating isolation region STI is disposed on the source region S, and a drain contact(s) CD of which the edge portion is contacted with the insulating isolation region STI is disposed on the drain region D. A gate contact GC is disposed on a gate electrode G extended in the Y direction. The size of the source contact CS is expressed by C1 in the X direction, and is expressed by C1 in the Y direction. The size of the drain contact CD and the size of the gate contact GC are expressed similarly to that of the source contact CS.

FIG. 1D illustrates an example of a schematic planar pattern configuration of a modified example if the semiconductor device 1A according to the first embodiment in which the active region AA is reduced so that an edge portion of the source contact CS and an edge portion of the drain contact CD are respectively run on the insulating isolation regions STI. As illustrated in FIG. 1D, the size in the X direction of the source region S is expressed by S4, the size in the Y direction thereof is expressed by W1, the size in the X direction of the drain region D is expressed by D4, and the size in the Y direction thereof is expressed by W1. In this case, S4<S3<S2<S1 is realized and D4<D3<D2<D1 is realized. The size in the X direction of the gate electrode G is expressed by L4. W1 and L4 respectively correspond to the channel width and the channel length. A source contact(s) CS of which the edge portion runs on the insulating isolation region STI is disposed on the source region S, and a drain contact(s) CD of which the edge portion runs on the insulating isolation region STI is disposed on the drain region D. A gate contact GC is disposed on a gate electrode G extended in the Y direction. The size of the source contact CS is expressed by C1 in the X direction, and is expressed by C1 in the Y direction. The size of the drain contact CD is expressed similarly to that of the source contact CS and that of the gate contact GC. Although the insulating isolation region (STI) has a predetermined width, this point is omitted in FIGS. 1A to 1D. Moreover, FIGS. 1A to 1D have been described for the first embodiment, but they are similarly applicable to the second embodiment.

(Mechanism of Increased Leakage)

It is effective to reduce the area of the active region AA and to reduce the distances between the source contact CS and the insulating isolation STI region and between the drain contact CD and the insulating isolation STI region, as illustrated in FIGS. 1A to 1D, as one of methods of reducing the transistor size. However, as the distance between the source contact CS and the insulating isolation region STI is reduced and the distance between the drain contact CD and the insulating isolation region STI is reduced, if the source contact CS and the drain contact CD respectively run on the insulating isolation regions STI, since the distance between the source contact and the source diffusion pn junction becomes shorter, a junction leakage increases. Since the pn junction between the source diffusion layer and the semiconductor region and the source contact CS interface are close to each other, a leakage current of the pn junction between the source diffusion layer and a p type semiconductor region is increased at the time of a depletion layer spreading in the channel when a bias voltage is applied between the drain and the source. If the source contact CS runs on the insulating isolation region STI, an edge portion of the p type semiconductor region (active region AA) is exposed when the source contact CS is opened. Since the source electrode enters therein, the distance between the source contact CS and the source diffusion layer of the edge portion of the active region AA is shortened, and thereby the junction leakage is increased.

In the semiconductor device according to the embodiments, the insulating isolation region STI is moved backward and recessed in the depth direction of the semiconductor region, and an insulating layer having a high selective ratio with respect to an oxide film and a nitride film is formed on a side wall of the semiconductor region exposed by this recess, thereby suppressing the junction leakage. Moreover, by forming the insulating layer having the high selective ratio with respect to the oxide film and the nitride film also on a gate side wall, the distance between the gate electrode G and the source contact CS can be controlled in a self-aligned manner. Similarly, the distance between the gate electrode G and the drain contact CD can also be controlled in a self-aligned manner. Consequently, the embodiments can provide a semiconductor device capable of suppressing an increase in a junction leakage and reducing a size thereof.

(Configuration of Semiconductor Device according to First Embodiment)

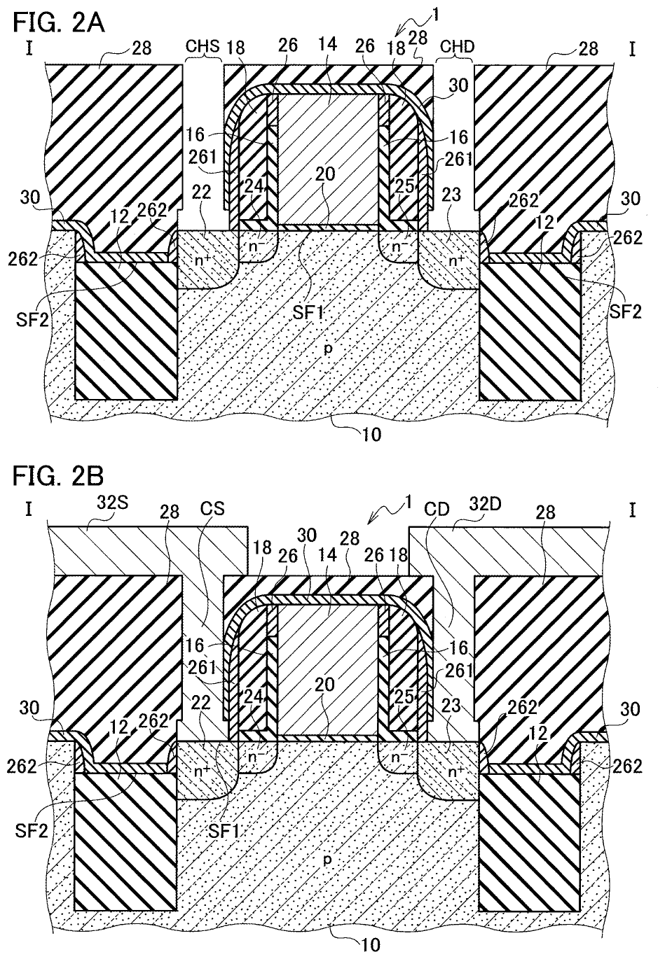

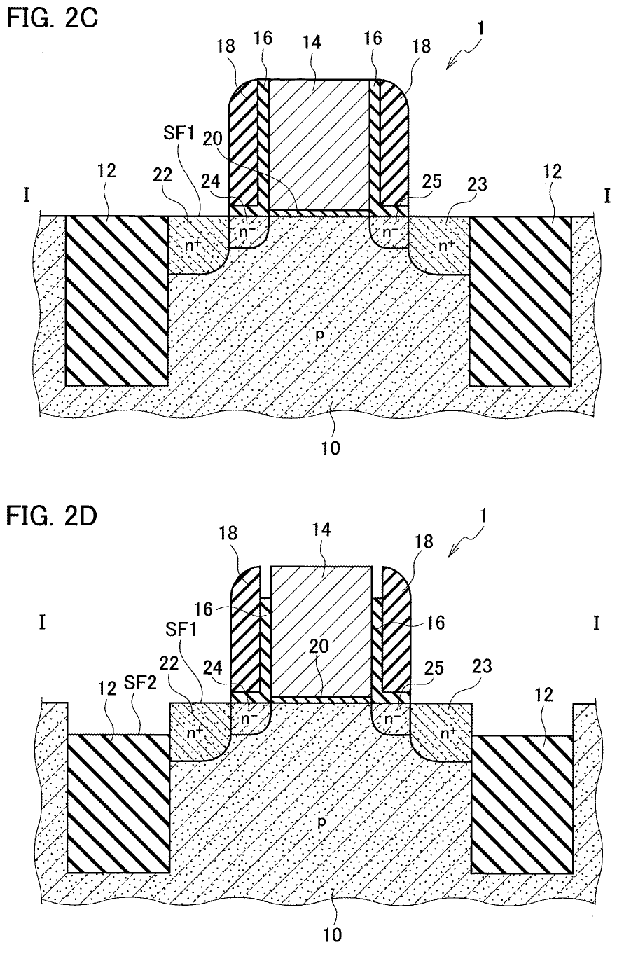

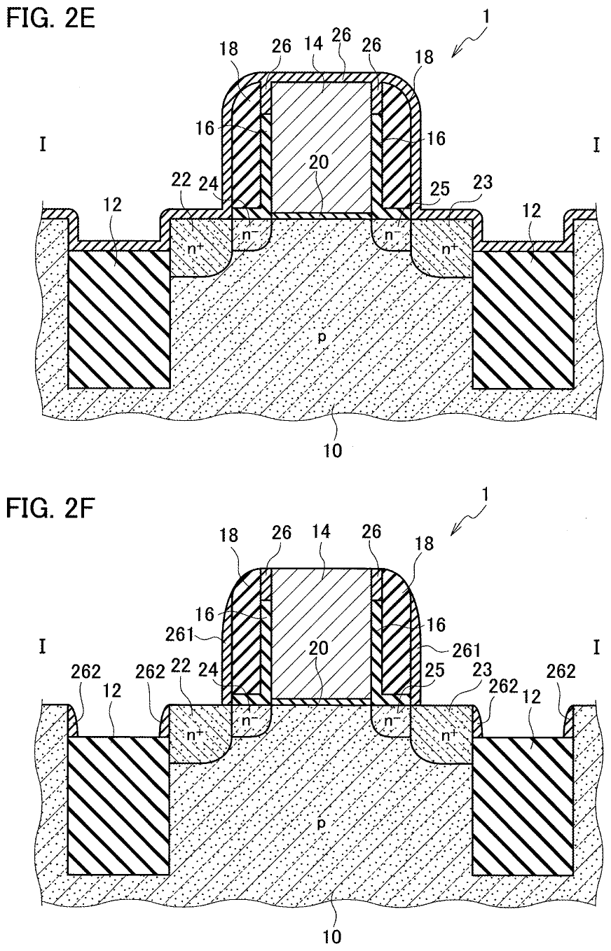

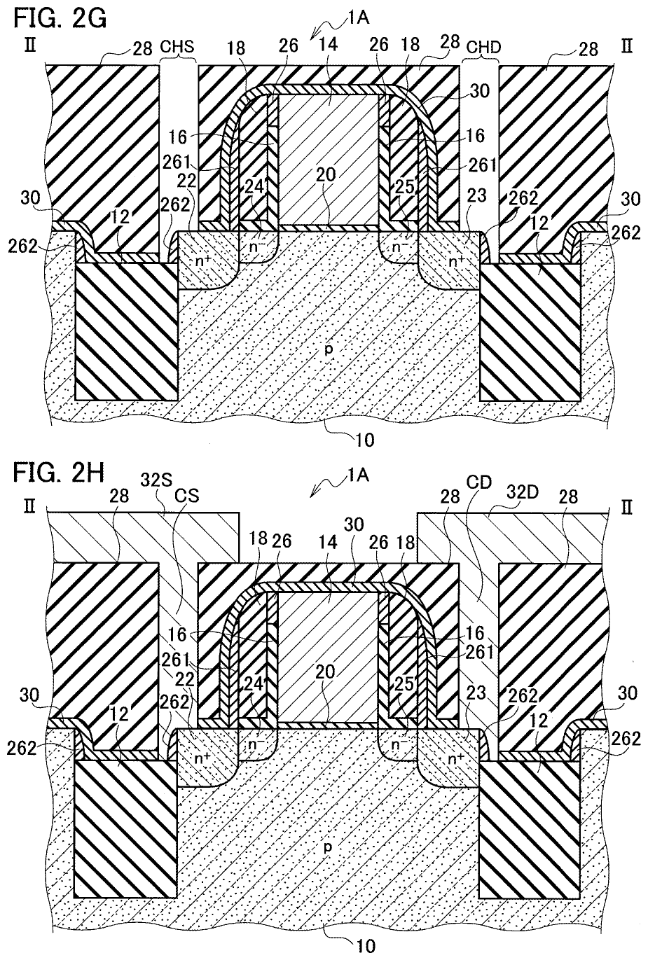

FIGS. 2A and 2B respectively illustrate schematic cross-sectional structures taken in the line I-I of FIG. 1C, in the semiconductor device 1 according to the first embodiment. FIG. 2A illustrates a structure in which a window of the source contact hole CHS is opened and a window of the drain contact hole CHD is opened, and FIG. 2B illustrates a structure in which the source contact CS and the drain contact CD are formed thereon.

The semiconductor device 1 according to the first embodiment includes a semiconductor region 10, an insulating portion 12, a first region (source) 22, a second region (drain) 23, a control electrode (gate electrode) 14, a first electrode CS, and a first insulating film 262. The semiconductor region 10 having a first conductivity type includes a first surface SF1. The insulating portion 12 is formed on the semiconductor region 10, and has a second surface SF2 formed so as to be moved backward in the depth direction of the semiconductor region 10 more than the first surface SF1. The first region 22 is disposed on the semiconductor region 10 between a first portion of the insulating portion 12 and a second portion of the insulating portion 12. The second region 23 is disposed on the semiconductor region 10 between the first portion and the second portion, and is located to be separated from the first region 22. The control electrode 14 is disposed above the first surface SF1, and is located between the first region and the second region 23. The first electrode CS is disposed on the first region 22 so as to be contacted with the first region 22. The first insulating film 262 is disposed on a side wall of the semiconductor region 10 at a stepped portion between the first surface SF1 and the second surface SF2. The first insulating film 262 is an insulating layer containing hafnium. The details will be described below.

As illustrated in FIG. 2A, the semiconductor device 1 according to the first embodiment includes: a first conductivity-type semiconductor region 10; an insulating isolation region 12; a gate electrode 14; a sidewall insulating film 261; a source region 22 and a drain region 23, each having a conductivity type opposite to the first conductivity type; a source contact hole CHS and a drain contact hole CHD;

a source electrode 32S; a drain electrode 32D; and a sidewall insulating film 262.

The semiconductor region 10 includes a p type semiconductor region formed by forming a p type well diffusion layer with respect to an n type semiconductor substrate, for example. The semiconductor region 10 may include a p type semiconductor substrate.

The insulating isolation region 12 is formed on the first surface SF1 of the semiconductor region 10, and has a second surface SF2 formed so as to be moved backward in the depth direction of the semiconductor region 10 more than the first surface SF1. The insulating isolation region 12 can be formed by STI. In addition, the insulating isolation region (STI) 12 has a predetermined width, as illustrated in FIGS. 2C to 2H. Moreover, the depth direction of the semiconductor region 10 is a direction vertical to the above-mentioned X-Y plane.

The gate electrode 14 is formed above the semiconductor region 10 surrounded by the insulating isolation region 12, via a gate oxide film 20.

The gate electrode 14 is disposed on the first surface SF1 and is located between the source region 22 and the drain region 23. The source electrode 32S is disposed on the source region 22 to be connected to the source region 22. The drain electrode 32D is disposed on the drain region 23 to be connected to the drain region 23.

The sidewall insulating film 261 is disposed on a side wall of each end of the gate electrode 14, and includes a film having a high selective etching ratio with respect to a silicon oxide film and a silicon nitride film.

The source region 22 and the drain region 23 are respectively formed on the first surface SF1 at the both ends of the gate electrode 14.

A source extension region 24 adjacent to the source region 22 and a drain extension region 25 adjacent to the drain region 23 are disposed on the first surface SF1 at the both ends of the gate electrode 14.

The source region 22 is disposed on the semiconductor region 10 between the insulating isolation regions 12. The drain region 23 is disposed on the semiconductor region 10 between the insulating isolation regions 12 and is located to be separated from the source region 22 in the X direction.

The source contact hole CHS is formed on the source region 22, and the drain contact hole CHD is formed on the drain region D.

As illustrated in FIG. 2B, the source electrode 32S composes the source contact CS by being electrically connected to the source region 22 via the source contact hole CHS, and the drain electrode 32D composes the drain contact CD by being electrically connected to the drain region 23 via the drain contact hole CHD.

The sidewall insulating film 262 is disposed on a side wall of the semiconductor region 10 at a stepped portion between the first surface SF1 and the second surface SF2, and includes an insulating layer having a high selective etching ratio with respect to a silicon oxide film and a silicon nitride film. The sidewall insulating film 262 may be formed simultaneously with the sidewall insulating film 261.

The sidewall insulating film 261 and the sidewall insulating film 262 may include a hafnium based oxide film, for example. The hafnium based oxide film is a film having a high selective etching ratio with respect to the silicon oxide film and the silicon nitride film, and the selective etching ratio thereof is equal to or greater than approximately 10.

The sidewall insulating film 261 and the sidewall insulating film 262 may contain any different material selected from the group consisting of HfOₓ, HfSiOₓ, and HfSiON, for example.

The thickness of the sidewall insulating film 261 and the sidewall insulating film 262 is within a range from several nm to several tens of nm. The thickness of the sidewall insulating film 261 and the sidewall insulating film 262 may be within a range from approximately 2 nm to approximately 20 nm.

The length in the depth direction from the first surface SF1 to the second surface SF2 is within a range from approximately several nm to several tens of nm. Moreover, the length in the depth direction from the first surface SF1 to the second surface SF2 may be within a range from approximately 10 nm to approximately 50 nm.

The sidewall insulating film 262 is formed on the side wall of the stepped portion between the first surface SF1 and the second surface SF2, and the edge portions of the semiconductor region 10 and the source region 22/the drain region 23, which are active regions AA, are covered with the sidewall insulating film 262 so as to be not exposed, thereby increase in the junction leakage can be suppressed.

A silicon oxide film 16 and a silicon nitride film 18 which are stacked on the side wall of the gate electrode 14, and the sidewall insulating film 261 is disposed to be stacked on the silicon nitride film 18.

The source contact CS may be disposed in contact with the interface between the insulating isolation region 12 and the source region 22, as illustrated in FIG. 2B. Similarly, the drain contact CD may be disposed in contact with the interface between the insulating isolation region 12 and the drain region 23, as illustrated in FIG. 2B.

In the semiconductor device according to the first embodiment, the insulating isolation region 12 is moved backward to be recessed in the depth direction of the semiconductor region 10, and the sidewall insulating film 262 having a high selective ratio with respect to the oxide film and the nitride film is formed on the side walls of the semiconductor region 10 and the source region 22/the drain region 23 which are exposed by the recessing, thereby the junction leakage can be suppressed.

Moreover, in the semiconductor device 1 according to the first embodiment, by forming the sidewall insulating film 261 having the high selective ratio with respect to the oxide film and the nitride film also on a gate side wall, the distance between the gate electrode 14 and the source contact CS can be controlled in a self-aligned manner. Similarly, the distance between the gate electrode 14 and the drain contact CD can also be controlled in a self-aligned manner. Consequently, the first embodiment can provide a semiconductor device capable of suppressing an increase in a junction leakage and reducing a size thereof.

(Configuration of Semiconductor Device according to Modified Example of First Embodiment)

FIGS. 2G and 2H respectively illustrate schematic cross-sectional structures taken in the line II-II of FIG. 1D, in a semiconductor device 1A according to a modified example of the first embodiment. FIG. 2G illustrates a structure in which a window of the source contact hole CHS is opened and a window of the drain contact hole CHD is opened, and FIG. 2H illustrates a structure in which the source contact CS and the drain contact CD are formed thereon.

As illustrated in FIG. 2G, the semiconductor device 1A according to the modified example of the first embodiment includes: a first conductivity-type semiconductor region 10; an insulating isolation region 12; a gate electrode 14; a sidewall insulating film 261; a source region 22 and a drain region 23; a source contact hole CHS and a drain contact hole CHD; and a sidewall insulating film 262.

Moreover, as illustrated in FIG. 2H, the source electrode 32S composes the source contact CS by being electrically connected to the source region 22 via the source contact hole CHS, and the drain electrode 32D composes the drain contact CD by being electrically connected to the drain region 23 via the drain contact hole CHD.

Moreover, the source contact CS may be disposed so as to straddle both the insulating isolation region 12 and the source region 22, as illustrated in FIG. 2H. Similarly, the drain contact CD may be disposed so as to straddle both the insulating isolation region 12 and the drain region 23, as illustrated in FIG. 2H. Other configurations are the same as those of the first embodiment.

Also in the semiconductor device 1A according to the modified example of the first embodiment, the insulating isolation region 12 is moved backward to be recessed in the depth direction of the semiconductor region 10, and the sidewall insulating film 262 having a high selective ratio with respect to the oxide film and the nitride film is formed on the side wall of the semiconductor region 10 and the source region 22/the drain region 23 which are exposed by the recessing, thereby the junction leakage can be suppressed.

Although the edge portion of the semiconductor region 10 and the source region 22 (and the edge portion of the semiconductor region 10 and the drain region 23) is exposed when the window of the source contact CS is opened if the source contact CS runs on the insulating isolation region 12, the sidewall insulating film 262 having a high selective ratio with respect to the oxide film and the nitride film is formed on the side wall, and thereby the junction leakage can be suppressed even if the source electrode 32S (and the drain electrode 32D) enters the opening on the insulating isolation region 12. More specifically, the junction leakage can be avoided even if the source electrode 32S and the drain electrode 32D step out on the STI. Consequently, the distance between the source contact CS and the insulating isolation region 12 can be shortened. Similarly, the distance between the drain contact CD and the insulating isolation region 12 can be shortened.

Moreover, also in the semiconductor device 1A according to the modified example of the first embodiment, by forming the sidewall insulating film 261 having the high selective ratio with respect to the oxide film and the nitride film also on a gate side wall, the distance between the gate electrode 14 and the source contact CS can be controlled in a self-aligned manner. Similarly, the distance between the gate electrode 14 and the drain contact CD can also be controlled in a self-aligned manner. Consequently, the modified example of the first embodiment can provide a semiconductor device capable of suppressing an increase in a junction leakage and reducing a size thereof.

(Fabrication Method of Semiconductor Device according to First Embodiment)

FIGS. 2A to 2F illustrate a fabrication method of the semiconductor device according to the first embodiment.

The fabrication method of the semiconductor device according to the first embodiment includes: forming an insulating portion 12 on a first surface SF1 of a first conductivity-type semiconductor region 10; forming a gate electrode 14 above the semiconductor region 10 surrounded by the insulating portion 12 via a gate oxide film 20; forming a source region 22 and a drain region 23 having a conductivity type opposite to the first conductivity type on the first surface SF1 at both ends of the gate electrode 14; etching the insulating portion 12 to a second surface SF2 which is moved backward in a depth direction of the semiconductor region 10 more than the first surface SF1; forming a first sidewall insulating film 262 containing hafnium on a side wall of the semiconductor region 10 of each stepped portion between the first surface SF1 and the second surface SF2, and forming a second sidewall insulating film 261 containing hafnium on a side wall at each end of the gate electrode 14; forming an interlayer insulating film 28; forming a contact hole CFS in the interlayer insulating film 28; and forming a source electrode CS connected to the source region 22 in the contact hole CFS. The details will be described below.
(A1) First, as illustrated in FIG. 2C, the insulating isolation region 12 is formed on the first surface SF1 of the p type semiconductor region 10, and the gate electrode 14 is formed above the semiconductor region 10 which is surrounded by the insulating isolation region 12 via the gate oxide film 20. In this case, the insulating isolation region 12 is formed of Tetraethoxysilane (TEOS), for example. The gate electrode 14 is formed of doped polysilicon or the like, for example.
(A2) Next, the silicon oxide film 16 is formed on the side wall of the gate electrode 14 by a Chemical Vapor Deposition (CVD) method, for example. In this case, the silicon oxide film 16 is formed of TEOS, for example.
(A3) Next, the n⁻ type source extension region 24 and the n⁻ type drain extension region 25 are respectively formed on the first surfaces SF1 at the both ends of the gate electrode 14, by using an ion implantation technique.
(A4) Next, the silicon nitride film 18 is formed, by using the CVD method, on the silicon oxide film 16 of the side wall of the gate electrode 14.
(A5) Next, the n⁺ type source region 22 and the n⁺ type drain region 23 are respectively formed on the first surfaces SF1 at the both ends of the gate electrode 14, by suing an ion implantation technique.
(B) Next, as illustrated in FIG. 2D, the front side surface of the insulating isolation region 12 is etched, by using a Reactive Ion Etching (RIE) technology, to form the STI having the second surface SF2 which is moved backward in the depth direction of the semiconductor region 10 more than the first surface SF1. As illustrated in FIG. 2D, the silicon oxide film 16 on the side wall of the gate electrode 14 is also etched simultaneously with the front side surface of the insulating isolation region 12.
(C) Next, as illustrated in FIG. 2E, the insulating layer 26 is formed on a whole surface of the device by using a sputtering technique or the like. The insulating layer 26 is a film having a high selective etching ratio with respect to the silicon oxide film and the silicon nitride film.
(D) Next, as illustrated in FIG. 2F, the insulating layer 26 is etched, in order to form the sidewall insulating film 261 disposed on the side wall of each ends of the gate electrode 14, and form a sidewall insulating films 262 on the side wall of the semiconductor region 10 at the stepped portion between the first surface SF1 and the second surface SF2, and the side wall of the n⁺ type source region 22/the type drain region 23. In the etching process of the insulating layer 26, after forming the insulating layer 26 on the whole surface of the device, it is patterned to be removed by dry etching or wet etching, before crystallizing. The dry etching and the wet etching may be used together.
(E1) Next, as illustrated in FIG. 2A, a liner insulating layer 30 is formed on the whole surface of the device by using the CVD technique or the like. In this case, the silicon nitride film can be applied to the liner insulating layer 30.
(E2) Next, as illustrated in FIG. 2A, after removing the liner insulating layer 30 formed on the source region 22 and the drain region 23 in order to expose the front side surface of the source region 22 and the front side surface of the drain region 23, and after the forming interlayer insulating film 28 on the whole surface of the device by using the CVD technique or the like, and it is planarized by using a Chemical Mechanical Polishing (CMP) technology. In this case, a None-doped Silicate Glass (NSG) film or the like as an insulating layer having a sufficient compatibility with the TEOS or CMP can be applied to the interlayer insulating film 28. By using the NSG film, the front side surface of the NSG film can be favorably planarized at a high polishing rate. Alternatively, the interlayer insulating film 28 may be formed on the whole surface of the device after forming the above-mentioned liner insulating layer 30.
(E3) Next, as illustrated in FIG. 2A, the source contact hole CHS and the drain contact hole CHD are respectively formed on the source region 22 and the drain region 23 with respect to the interlayer insulating film 28, by using dry etching technology, such as RIE.

In addition, when the interlayer insulating film 28 is formed on the whole surface of the device after forming the above-mentioned liner insulating layer 30, the liner insulating layer 30 formed on the source region 22 and the drain region 23 is removed simultaneously with the window opening of the source contact hole CHS and the window opening of the drain contact hole CHD with respect to the interlayer insulating film 28, so that the front side surface of the source region 22 and the front side surface of the drain region 23 are exposed.
(F) Next, as illustrated in FIG. 2B, the source electrode 32S and the drain electrode 32D respectively connected to the source region 22 and the drain region 23 via the source contact hole CHS and the drain contact hole CHD are formed. The source electrode 32S forms the source contact CS by being electrically connected to the source region 22 via the source contact hole CHS, and the drain electrode 32D forms the drain contact CD by being electrically connected to the drain region 23 via the drain contact hole CHD. The source contact CS may be disposed in contact with the interface between the insulating isolation region 12 and the source region 22, as illustrated in FIG. 2B. Similarly, the drain contact CD may be disposed in contact with the interface between the insulating isolation region 12 and the drain region 23, as illustrated in FIG. 2B.

As illustrated in FIG. 2A, since the sidewall insulating films 261 are respectively formed on the side walls at the both ends of the gate electrode 14, the sidewall insulating film 261 is relatively hard to be etched even if the interlayer insulating film 28 and the liner insulating layer 30 are over-etched when forming the source contact hole CHS and the drain contact hole CHD. More specifically, when forming the source contact hole CHS and the drain contact hole CHD, the etching is stopped in a self-aligned manner by sidewall insulating film 261. Accordingly, the distance between the source contact CS and the gate electrode 14 can be shortened. Similarly, the distance between the drain contact CD and the gate electrode 14 can be shortened.

Since the sidewall insulating film 262 is formed on the side wall of the semiconductor region 10 at the stepped portion between the first surface SF1 and the second surface SF2, the interlayer insulating film 28 and the liner insulating layer 30 are easily etched, but the sidewall insulating film 262 is relatively hard to be etched, when forming the source contact hole CHS and the drain contact hole CHD. Consequently, the junction leakage can be avoided even if the source contact hole CHS and the drain contact hole CHD are in contact with the insulating isolation region 12, as illustrated in FIG. 2B. Accordingly, the distance between the source contact CS and the insulating isolation region 12 can be shortened. Similarly, the distance between the drain contact CD and the insulating isolation region 12 can be shortened.

(Fabrication Method of Semiconductor Device according to Modified Example of First Embodiment)

FIGS. 2C to 2F, 2G, and 2H illustrate a fabrication method of the semiconductor device according to the modified example of the first embodiment.

Steps A1 to A5 and steps B to D in the fabrication method of the semiconductor device according to the first embodiment are common also to the fabrication method of the semiconductor device according to the modified example of the first embodiment.
(G1) After the above-mentioned step D, the liner insulating layer 30 is formed on the whole surface of the device by using the CVD technique or the like, as illustrated in FIG. 2G. In this case, the silicon nitride film can be applied to the liner insulating layer 30.
(G2) Next, as illustrated in FIG. 2G, after the forming the interlayer insulating film 28, it is planarized by using the CMP technique. In this case the TEOS or the NSG film can be applied to the interlayer insulating film 28, for example. By using the NSG film, the front side surface of the NSG film can be favorably planarized at a high polishing rate.
(G3) Next, as illustrated in FIG. 2G, by using dry etching technology, such as RIE, with respect to the interlayer insulating film 28, the source contact hole CHS is formed so as to straddle both the source region 22 and the insulating isolation region 12, and the drain contact hole CHD is formed so as to straddle both the drain region 23 and the insulating isolation region 12.
(H) Next, as illustrated in FIG. 2H, the source electrode 32S and the drain electrode 320 respectively connected to the source region 22 and the drain region 23 via the source contact hole CHS and the drain contact hole CHD are formed. The source electrode 32S forms the source contact CS by being electrically connected to the source region 22 via the source contact hole CHS, and the drain electrode 32D forms the drain contact CD by being electrically connected to the drain region 23 via the drain contact hole CHD.

Since the sidewall insulating film 262 is formed on the side wall of the semiconductor region 10 at the stepped portion between the first surface SF1 and the second surface SF2, The interlayer insulating film 28 and the liner insulating layer 30 are easily etched, but the sidewall insulating film 262 is relatively hard to be etched, when forming the source contact hole CHS and the drain contact hole CHD. Consequently, the junction leakage can also be avoided even if the source contact CS and the drain contact CD step out on the insulating isolation region 12, as illustrated in FIG. 2H. Accordingly, the distance between the source contact CS and the insulating isolation region 12 can be shortened. Similarly, the distance between the drain contact CD and the insulating isolation region 12 can be shortened.

### Second Embodiment

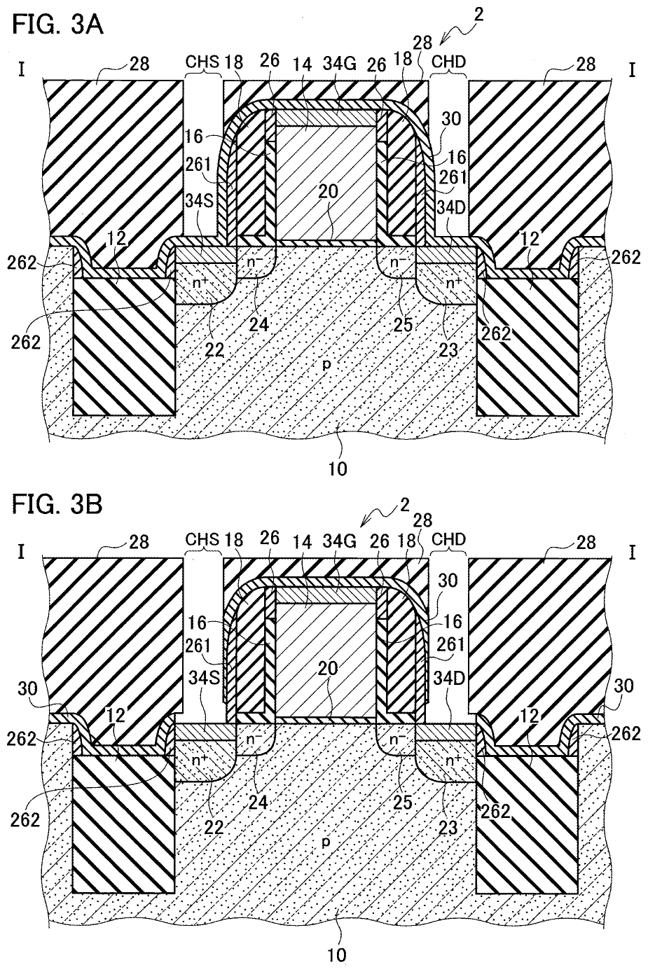

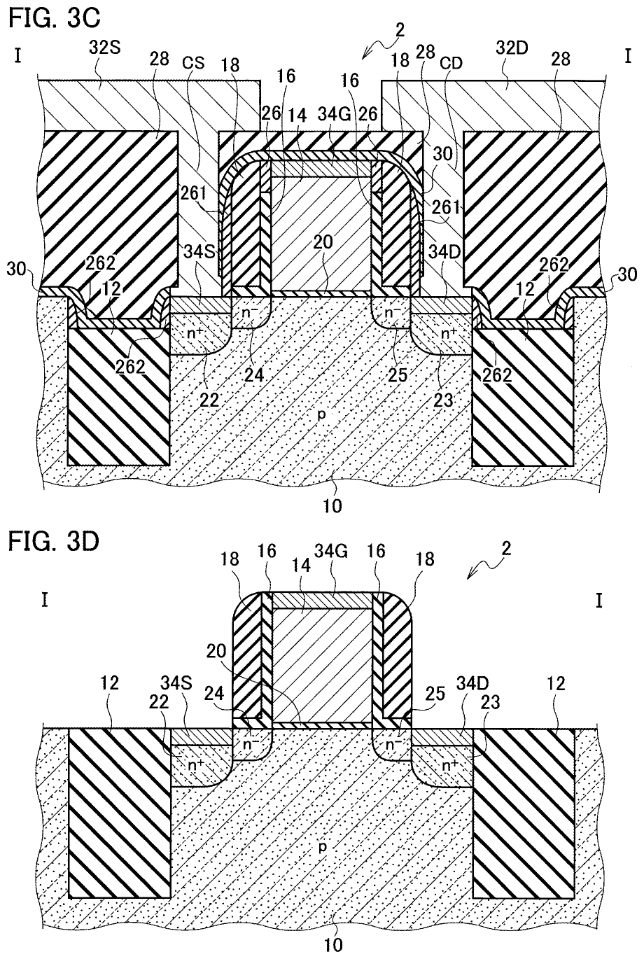

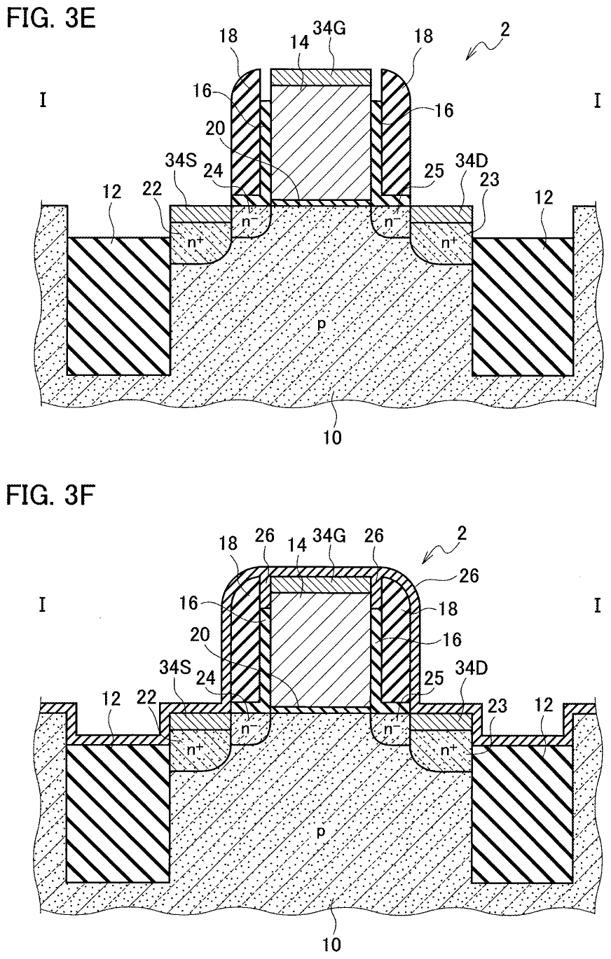

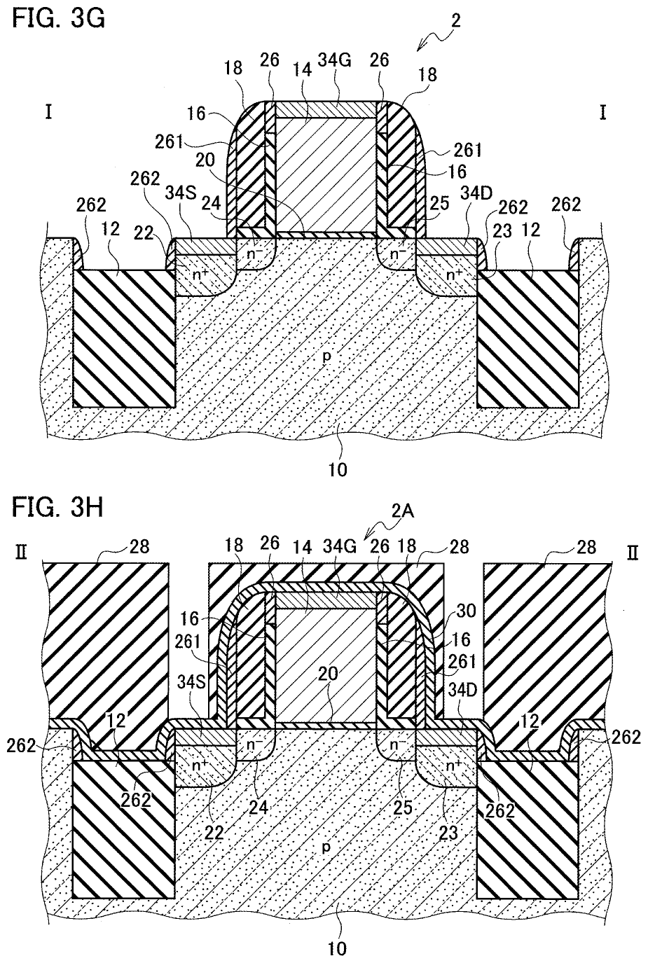

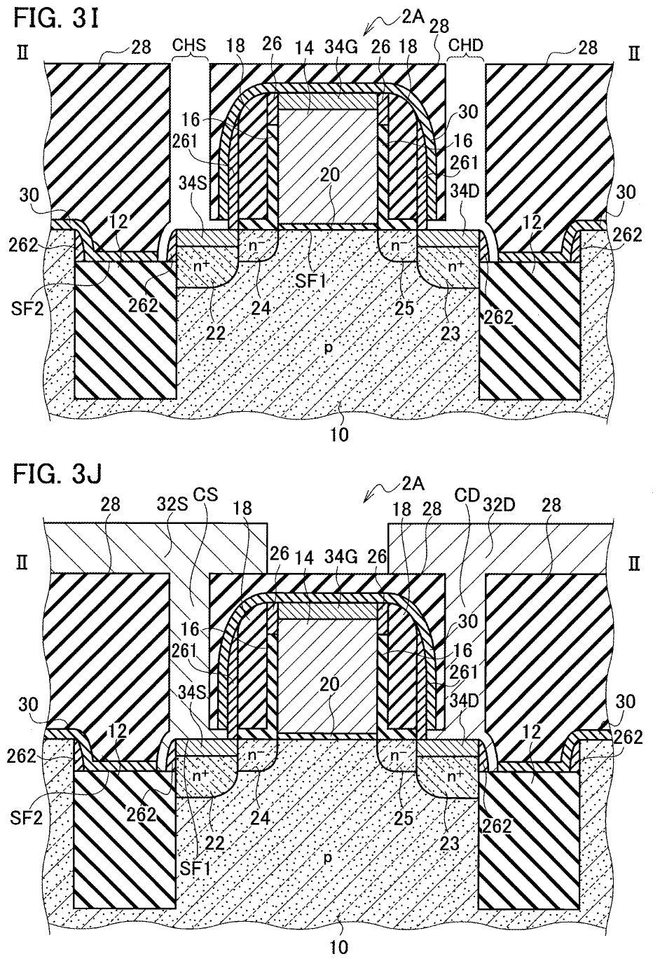

FIGS. 3A and 3C respectively illustrate schematic cross-sectional structures taken in the line I-I of FIG. 1C, in a semiconductor device 2 according to a second embodiment.

As illustrated in FIGS. 3A to 3C, the semiconductor device 2 according to the second embodiment includes: a first conductivity-type semiconductor region 10; an insulating isolation region 12; a gate electrode 14; a sidewall insulating film 261; a source region 22 and a drain region 23; a source contact hole CHS and a drain contact hole CHD; and a source electrode 32S; a drain electrode 32D; a sidewall insulating film 262; a gate silicide region 34G disposed on the gate electrode 14; a source silicide region 34S disposed on the source region 22; and a drain silicide region 34D disposed on the drain region 23.

The source silicide region 34S and the drain silicide region 34D include any different silicide selected from the group consisting of Co, W, Ti, and Ni. The gate silicide region 34G includes any different element selected from the group consisting of Co, W, Ti, and Ni.

Moreover, as illustrated in FIG. 3C, the source electrode 32S composes the source contact CS by being electrically connected to the source silicide region 34S via the source contact hole CHS, and the drain electrode 32D composes the drain contact CD by being electrically connected to the drain silicide region 34D via the drain contact hole CHD.

The source contact CS may be disposed in contact with the interface between the insulating isolation region 12 and the source region 22/the source silicide region 34S, as illustrated in FIG. 3C. Similarly, the drain contact CD may be disposed in contact with the interface between the insulating isolation region 12 and the drain region 23/the drain silicide region 34D, as illustrated in FIG. 3C. Other configurations are the same as those of the first embodiment.

In the semiconductor device according to the second embodiment, the insulating isolation region 12 is moved backward to be recessed in the depth direction of the semiconductor region 10, and the sidewall insulating film 262 having a high selective ratio with respect to the oxide film and the nitride film is formed on the side walls of the semiconductor region 10 and the source silicide region 34S/the drain silicide region 34D which are exposed by the recessing, thereby the junction leakage can be suppressed.

Moreover, in the semiconductor device 2 according to the second embodiment, by forming the sidewall insulating film 261 having the high selective ratio with respect to the oxide film and the nitride film also on a gate side wall, the distance between the gate electrode 14 and the source contact CS can be controlled in a self-aligned manner. Similarly, the distance between the gate electrode 14 and the drain contact CD can also be controlled in a self-aligned manner. Consequently, the second embodiment can provide a semiconductor device capable of suppressing an increase in a junction leakage and reducing a size thereof.

(Configuration of Semiconductor Device according to Modified Example of Second Embodiment)

FIGS. 3H and 3J respectively illustrate schematic cross-sectional structures taken in the line II-II of FIG. 1D, in a semiconductor device 2A according to a modified example of the second embodiment.

As illustrated in FIGS. 3H to 3J, the semiconductor device 2A according to the modified example of the second embodiment includes: a semiconductor region 10; an insulating isolation region 12; a gate electrode 14; a sidewall insulating film 261; a source region 22 and a drain region 23; a source contact hole CHS and a drain contact hole CHD; a sidewall insulating film 262; a gate silicide region 34G disposed on the gate electrode 14; a source silicide region 34S disposed on the source region 22; and a drain silicide region 34D disposed on the drain region 23.

The source silicide region 34S and the drain silicide region 34D include any different silicide selected from the group consisting of Co, W, Ti, and Ni. The gate silicide region 34G includes any different silicide selected from the group consisting of Co, W, Ti, Ni, and polysilicon.

Moreover, as illustrated in FIG. 3J, the source electrode 32S composes the source contact CS by being electrically connected to the source silicide region 34S via the source contact hole CHS, and the drain electrode 32D composes the drain contact CD by being electrically connected to the drain silicide region 34D via the drain contact hole CHD.

Moreover, the source contact CS may be disposed so as to straddle both the insulating isolation region 12 and the source region 22/the source silicide region 34S, as illustrated in FIG. 3J. Similarly, the drain contact CD may be disposed so as to straddle both the insulating isolation region 12 and the drain region 23/the drain silicide region 34D, as illustrated in FIG. 3J. Other configurations are the same as those of the second embodiment.

Also in the semiconductor device 2A according to the modified example of the second embodiment, the insulating isolation region 12 is moved backward to be recessed in the depth direction of the semiconductor region 10, and the sidewall insulating film 262 having a high selective ratio with respect to the oxide film and the nitride film is formed on the side walls of the semiconductor region 10 and the source silicide region 34S/the drain silicide region 34D which are exposed by the recessing, thereby the junction leakage can be suppressed.

Although the edge portion of the semiconductor region 10 and the source silicide region 34S (and the edge portion of the semiconductor region 10 and the drain silicide region 34D) is exposed when the window of the source contact CS is opened if the source contact CS runs on the insulating isolation region 12, the sidewall insulating film 262 having a high selective ratio with respect to the oxide film and the nitride film is formed on the side wall, and thereby the junction leakage can be suppressed even if the source electrode 32S (and the drain electrode 32D) enters the opening on the insulating isolation region 12. More specifically, the junction leakage can be avoided even if the source electrode 32S and the drain electrode 32D step out on the STI. Consequently, the distance between the source contact CS and the insulating isolation region 12 can be shortened. Similarly, the distance between the drain contact CD and the insulating isolation region 12 can be shortened.

Moreover, also in the semiconductor device 2A according to the modified example of the second embodiment, by forming the sidewall insulating film 261 having the high selective ratio with respect to the oxide film and the nitride film also on a gate side wall, the distance between the gate electrode 14 and the source contact CS can be controlled in a self-aligned manner. Similarly, the distance between the gate electrode 14 and the drain contact CD can also be controlled in a self-aligned manner. Consequently, the modified example of the second embodiment can provide a semiconductor device capable of suppressing an increase in a junction leakage and reducing a size thereof.

(Fabrication Method of Semiconductor Device according to Second Embodiment)

FIGS. 3A to 3G illustrate a fabrication method of the semiconductor device according to the second embodiment.
(A1) First, as illustrated in FIG. 3D, the insulating isolation region 12 is formed on the first surface SF1 of the semiconductor region 10, and the gate electrode 14 is formed above the semiconductor region 10 which is surrounded by the insulating isolation region 12 via the gate oxide film 20. In this case, the insulating isolation region 12 is formed of TEOS, for example. The gate electrode 14 is formed of doped polysilicon or the like, for example.
(A2) Next, the silicon oxide film 16 is formed on the side wall of the gate electrode 14 by using a CVD method. In this case, the silicon oxide film 16 is formed of TEOS, for example.
(A3) Next, the n⁻ type source extension region 24 and the n⁻ type drain extension region 25 are respectively formed on the first surfaces SF1 at the both ends of the gate electrode 14, by using an ion implantation technique.
(A4) Next, the silicon nitride film 18 is formed, by using the CVD method, on the silicon oxide film 16 of the side wall of the gate electrode 14.
(A5) Next, the n⁺ type source region 22 and the n⁺ type drain region 23 are respectively formed on the first surfaces SF1 at the both ends of the gate electrode 14, by suing an ion implantation technique.
(A6) Next, a silicide metal is formed in the whole surface of the device, the gate silicide region 34G is formed on the gate electrode 14, the source silicide region 34S is formed on the source region 22, and the drain silicide region 34D is formed on the drain region 23. A sheet resistance and a contact resistance can be reduced by forming the metal silicide which is a compound of a metal and silicon on the front side surface of the source region 22, the front side surface of the drain region 23, and the front side surface of the gate electrode 14. Moreover, the silicide can be formed in a self-aligned manner. The source silicide region 34S and the drain silicide region 34D may include any different silicide selected from the group consisting of Co, W, Ti, and Ni. The gate silicide region 34G may include any different element selected from the group consisting of Co, W, Ti, and Ni.
(B) Next, as illustrated in FIG. 3E, the front side surface of the insulating isolation region 12 is etched, by using the RIE technology, to form the STI having the second surface SF2 which is moved backward in the depth direction of the semiconductor region 10 more than the first surface SF1. As illustrated in FIG. 3B, the silicon oxide film 16 on the side wall of the gate electrode 14 is also etched simultaneously with the front side surface of the insulating isolation region 12.
(C) Next, as illustrated in FIG. 3F, the insulating layer 26 is formed on a whole surface of the device by using a sputtering technique or the like. The insulating layer 26 is a film having a high selective etching ratio with respect to the silicon oxide film and the silicon nitride film.
(D) Next, as illustrated in FIG. 3G, the insulating layer 26 is etched to form the sidewall insulating film 261 on the side walls of the both ends of the gate electrode 14. Moreover, the sidewall insulating film 262 is formed on the side wall at the stepped portion between the first surface SF1 and the second surface SF2. The sidewall insulating film 262 can guard the exposed surfaces of the semiconductor region 10 at the stepped portion between the first surface SF1 and the second surface SF2, the n⁺ type source region 22, the source silicide region 34S, the n⁺ type drain region 23, and the drain silicide region 34D. In the etching process of the insulating layer 26, after forming the insulating layer 26 on the whole surface of the device, it is patterned to be removed by dry etching or wet etching, before crystallizing. The dry etching and the wet etching may be used together.
(E1) Next, as illustrated in FIG. 3A, a liner insulating layer 30 is formed on the whole surface of the device by using the CVD technique or the like. In this case, the silicon nitride film can be applied to the liner insulating layer 30.
(E2) Next, as illustrated in FIG. 3A, after forming the interlayer insulating film 28 on the whole surface of the device by using the CMP technique, it is planarized by using the CVD technique or the like. In this case the TEOS or the NSG film can be applied to the interlayer insulating film 28, for example.
(E3) Next, as illustrated in FIG. 3A, the interlayer insulating film 28 is etched, by using the dry etching technology, such as RIE, so as to be stopped at the liner insulating layer 30 which covers the source silicide region 34S and the drain silicide region 34D, and thereby the liner insulating layer 30 is exposed at the bottom of the source contact hole CHS and the drain contact hole CHD.
(F) Next, as illustrated in FIG. 3B, the liner insulating layer 30 which covers the source silicide region 34S and the drain silicide region 34D is etched, by using the dry etching technology, such as RIE, and thereby the source contact hole CHS and the drain contact hole CHD are respectively formed on the source silicide region 34S and the drain silicide region 34D.
(G) Next, as illustrated in FIG. 3C, the source electrode 32S and the drain electrode 32D respectively connected to the source silicide region 34S and the drain silicide region 34D via the source contact hole CHS and the drain contact hole CHD are formed. The source electrode 32S forms the source contact CS by being electrically connected to the source region 22 via the source contact hole CHS, and the drain electrode 32D forms the drain contact CD by being electrically connected to the drain region 23 via the drain contact hole CHD. The source contact CS may be disposed in contact with the interface between the insulating isolation region 12 and the source region 22, as illustrated in FIG. 3C. Similarly, the drain contact CD may be disposed in contact with the interface between the insulating isolation region 12 and the drain region 23, as illustrated in FIG. 3C.

As illustrated in FIG. 3B, since the sidewall insulating films 261 are respectively formed on the side walls at the both ends of the gate electrode 14, the sidewall insulating film 261 is relatively hard to be etched even if the interlayer insulating film 28 and the liner insulating layer 30 are over-etched when forming the source contact hole CHS and the drain contact hole CHD. More specifically, when forming the source contact hole CHS and the drain contact hole CHD, the etching is stopped in a self-aligned manner by sidewall insulating film 261. Accordingly, the distance between the source contact CS and the gate electrode 14 can be shortened. Similarly, the distance between the drain contact CD and the gate electrode 14 can be shortened.

Since the sidewall insulating film 262 is formed on the side wall of the semiconductor region 10 at the stepped portion between the first surface SF1 and the second surface SF2, the interlayer insulating film 28 and the liner insulating layer 30 are easily etched, but the sidewall insulating film 262 is relatively hard to be etched, when forming the source contact hole CHS and the drain contact hole CHD. Consequently, the junction leakage can be avoided even if the source contact hole CHS and the drain contact hole CHD are in contact with the insulating isolation region 12, as illustrated in FIG. 3C. Accordingly, the distance between the source contact CS and the insulating isolation region 12 can be shortened. Similarly, the distance between the drain contact CD and the insulating isolation region 12 can be shortened.

(Fabrication Method of Semiconductor Device according to Modified Example of second Embodiment)

FIGS. 3A to 3D and 3H to 3J illustrate a fabrication method of the semiconductor device 2A according to the modified example of the second embodiment.

Steps A1 to A6 and steps B to D in the fabrication method of the semiconductor device according to the second embodiment are common also to the fabrication method of the semiconductor device 2A according to the modified example of the second embodiment.
(H1) After the above-mentioned step D, the liner insulating layer 30 is formed on the whole surface of the device by using the CVD technique or the like, as illustrated in FIG. 3H. In this case, the silicon nitride film can be applied to the liner insulating layer 30.
(H2) Next, as illustrated in FIG. 3H, after forming the interlayer insulating film 28 on the whole surface of the device by using the CMP technique, it is planarized by using the CVD technique or the like. In this case the TEOS or the NSG film can be applied to the interlayer insulating film 28, for example.
(H3) Next, as illustrated in FIG. 3H, the interlayer insulating film 28 is etched, by using the dry etching technology, such as RIE, so as to be stopped at the liner insulating layer 30 which covers the source silicide region 34S and the drain silicide region 34D, and thereby the liner insulating layer 30 is exposed at the bottom of the source contact hole CHS and the drain contact hole CHD.
(I) Next, as illustrated in FIG. 3I, the liner insulating layer 30 which covers the source silicide region 34S and the drain silicide region 34D is etched, by using the dry etching technology, such as RIE, and thereby the source contact hole CHS is formed so as to straddle both (to range over) the source silicide region 34S and the insulating isolation region 12, and the drain contact hole CHD is formed so as to straddle both the drain silicide region 34D and the insulating isolation region 12.
(J) Next, as illustrated in FIG. 3J, the source electrode 32S and the drain electrode 32D respectively connected to the source silicide region 34S and the drain silicide region 34D via the source contact hole CHS and the drain contact hole CHD are formed. The source electrode 32S forms the source contact CS by being electrically connected to the source region 22 via the source contact hole CHS, and the drain electrode 32D forms the drain contact CD by being electrically connected to the drain region 23 via the drain contact hole CHD.

Since the sidewall insulating film 262 is formed on the side wall of the semiconductor region 10 at the stepped portion between the first surface SF1 and the second surface SF2, the interlayer insulating film 28 and the liner insulating layer 30 are easily etched, but the sidewall insulating film 262 is relatively hard to be etched, when forming the source contact hole CHS and the drain contact hole CHD. Consequently, the junction leakage can also be avoided even if the source contact CS and the drain contact CD step out on the insulating isolation region 12, as illustrated in FIG. 3J. Accordingly, the distance between the source contact CS and the insulating isolation region 12 can be shortened. Similarly, the distance between the drain contact CD and the insulating isolation region 12 can be shortened.

In the semiconductor device according to the embodiments and the fabrication method thereof, although the n channel MOSFET has mainly been described, the same can be applied to a p-channel MOSFET having a conductivity type is reversed. Moreover, the semiconductor device according to the embodiments can be applied also to a high-speed logic LSI having a CMOS structure. Moreover, the semiconductor device according to the embodiments can be applied to a high-voltage pMOSFET, a high-voltage nMOSFET, a low-voltage pMOSFET, a low-voltage nMOSFET, and the like which compose a peripheral circuit of NAND flash memories, for example.

While certain embodiments have been described, these embodiments have been presented by way of examples only, and are not intended to limit the scope of the inventions. Indeed, the novel methods and systems described herein may be embodied in a variety of other forms; furthermore, various omissions, substitutions, and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductivity-type semiconductor region comprising a first surface;
an insulating portion formed on the semiconductor region, the insulating portion including a second surface formed so as to be moved backward in a depth direction of the semiconductor region more than the first surface;
a first region disposed on the semiconductor region between the first portion of the insulating portion and the second portion of the insulating portion;
a second region disposed on the semiconductor region between the first portion and the second portion, the second region located to be separated from the first region;
a control electrode disposed above the first surface, the control electrode located between the first region and the second region;
a first electrode disposed on the first region so as to be contacted with the first region; and
a first insulating film disposed on a side wall of the semiconductor region at a stepped portion between the first surface and the second surface, wherein
the first insulating film is an insulating layer containing hafnium.

2. The semiconductor device according to claim 1, further comprising
a second insulating film disposed on a side wall of each end of the control electrode.

3. The semiconductor device according to claim 2, wherein
the first insulating film and the second insulating film comprise a hafnium based oxide film.

4. The semiconductor device according to claim 3, wherein
the first insulating film and the second insulating film comprise any different material selected from the group consisting of HfOx, HfSiOx, and HfSiON.

5. The semiconductor device according to claim 2, wherein
a thickness of the first insulating film and the second insulating film is within a range from 2 nm to 20 nm.

6. The semiconductor device according to claim 2, wherein
a length in the depth direction from the first surface to the second surface is within a range from 2 nm to 20 nm.

7. The semiconductor device according to claim 2, wherein
a silicon oxide film and a silicon nitride film are sequentially stacked on the side wall of the control electrode, and the second insulating film is stacked on the silicon nitride film stacked on the side wall of the control electrode.

8. The semiconductor device according to claim 1, wherein
the first electrode is disposed in contact with an interface between the insulating portion and the first region.

9. The semiconductor device according to claim 1, wherein
the first electrode is disposed so as to straddle both the insulating portion and the first region.

10. The semiconductor device according to claim 1, wherein
the control electrode, the first region, and the second region respectively comprise silicide regions.

11. The semiconductor device according to claim 10, wherein
the silicide region comprises any different element selected from the group consisting of Co, W, Ti, and Ni.

12. A fabrication method of a semiconductor device, the fabrication method comprising:
forming an insulating portion on a first surface of a first conductivity-type semiconductor region;
forming a gate electrode above the semiconductor region surrounded by the insulating portion, via a gate oxide film;
forming a source region and a drain region respectively on the first surfaces of both ends of the gate electrode, the source region and the drain region having a conductivity type opposite to the first conductivity type;
etching an insulating portion to a second surface, the second surface being moved backward in a depth direction of the semiconductor region more than the first surface;
forming a first sidewall insulating film containing hafnium on a side wall of the semiconductor region at a stepped portion between the first surface and the second surface;
forming a second sidewall insulating film containing hafnium on a side wall of both ends of the gate electrode;
forming an interlayer insulating film;
forming a contact hole in the interlayer insulating film; and
forming a source electrode connected to the source region in the contact hole.

13. The fabrication method of the semiconductor device according to claim 12, wherein
the first sidewall insulating film and the second sidewall insulating film comprise any different material selected from the group consisting of HfOx, HfSiOx, and HfSiON.

14. The fabrication method of the semiconductor device according to claim 12, wherein
the contact hole is formed in contact with an interface between the insulating portion and the source region.

15. The fabrication method of the semiconductor device according to claim 12, wherein
the contact hole is formed so as to straddle both the insulating portion and the source region.

16. The fabrication method of the semiconductor device according to claim 12, further comprising
a gate silicide region is formed on the gate electrode, and a source silicide region is formed on the source region.

17. The fabrication method of the semiconductor device according to claim 16, wherein
the gate silicide region and the source silicide region comprise ant different element selected from the group consisting of Co, W, Ti, and Ni.
